(19) United States
(12) Patent Application Publication
(10) Pub. No.: US 2017/0123702 A1
(43) Pub. Date: May 4, 2017

(54) PROVIDING BACKUP POWER

(71) Applicant: Hewlet Packard Enterprise Development LP, Houston, TX (US)

(72) Inventors: Vincent NGUYEN, Houston, TX (US); Han WANG, Sugar Land, TX (US); Patrick A. RAYMOND, Houston, TX (US); Raghavan V. VENUGOPAL, Spring, TX (US)

(21) Appl. No.: 15/116,698

(22) PCT Filed: Apr. 1, 2014
(86) PCT No.: PCT/US2014/032480

§ 371 Date: Aug. 4, 2016

(51) Int. Cl. G06F 3/06; G06F 1/26; G11C 16/30; G11C 14/00

(52) U.S. Cl. CPC G06F 3/0625; G06F 3/0688; G06F 3/0655; G11C 14/0018; G06F 1/266; G11C 16/30

(57) ABSTRACT

A technique for providing backup power can include determining a backup power demand of at least two nodes on a chassis, each node supporting multiple loads. A technique for providing backup power can include selectively enabling an output of power from a battery module to the at least two nodes.

### BACKGROUND

As reliance on computing systems continues to grow, so too does the demand for reliable power systems and back-up schemes for these computing systems. Servers, for example, may provide architectures for backing up data to flash or persistent memory as well as back-up power sources for powering this back-up of data after the loss of power. Backup power sources may sometimes include energy components such as capacitors or batteries.

### BRIEF DESCRIPTION OF THE DRAWINGS

FIG. 1 illustrates a block diagram of an example of a computing device according to the present disclosure.

FIG. 2 illustrates a block diagram of an example of a system for providing backup power according to the present disclosure.

FIG. 3 illustrates a block diagram of an example of a system for providing backup power according to the present disclosure.

FIG. 4 illustrates a diagram of an example of array control logic according to the present disclosure.

FIG. 5 illustrates a flow diagram of an example of a method for providing backup power according to the present disclosure.

### DETAILED DESCRIPTION

A data storage system can include a number of nodes that support a number of loads. A data storage system can include a backup power system operatively coupled to the at least the number of nodes to support the number of loads in an event of a removal of a primary power supply. The power system can include a battery module and a backup power controller module that determines a backup power demand of at least one load to the number of loads and selectively provide backup power from the battery module to the number of loads in parallel.

The nodes can represent a number of servers, for example. Furthermore, the loads can represent cache memory.

A removal of a primary power supply can be a scheduled and/or an un-scheduled primary power supply removal. A scheduled removal of a primary power supply can be a scheduled removal of the primary power supply. For instance, a scheduled removal of the primary power supply can be the result of scheduled maintenance on the number of nodes and/or the number of loads. A scheduled removal of the primary power supply can be an intentional power down of the number of nodes and/or the number of loads to add and/or remove nodes to a chassis and/or network connected to a primary power supply.

An un-scheduled primary power supply removal can be an failure in the primary power supply. An un-scheduled primary power supply removal can occur when, for example, the primary power supply fails momentarily and/or permanently.

There can be a need to move data from cache memory in the number of loads to non-volatile memory upon the removal of a primary power supply. However, moving data from cache memory to non-volatile memory can require a power supply. A backup power supply can be a secondary power supply that is used to provide power for moving data from cache memory to non-volatile memory.

In a number of previous examples, the backup power for moving data from cache memory to non-volatile memory may include providing each node with a separate backup power supply. That is, if there are two nodes then each node is coupled to a separate backup power supply.

However, in the present disclosure, a backup power supply can provide backup power for a number of nodes. Providing a backup power supply for a number of nodes can save costly space and overhead over providing multiple backup power supplies for multiple nodes. In a number of examples, less costly components can be used in the backup power supply due to the added amount of time provided for supplying backup power as compared to providing multiple backup power supplies for multiple nodes. Providing a backup power for a number of nodes can reduce the costs associated with providing the multiple backup power supplies and maintaining the multiple backup power supplies. Furthermore, selectively providing a backup power can afford a greater amount of time and support a greater number of nodes and/or loads as compared to multiple backup power supplies that provide backup power to multiple nodes.

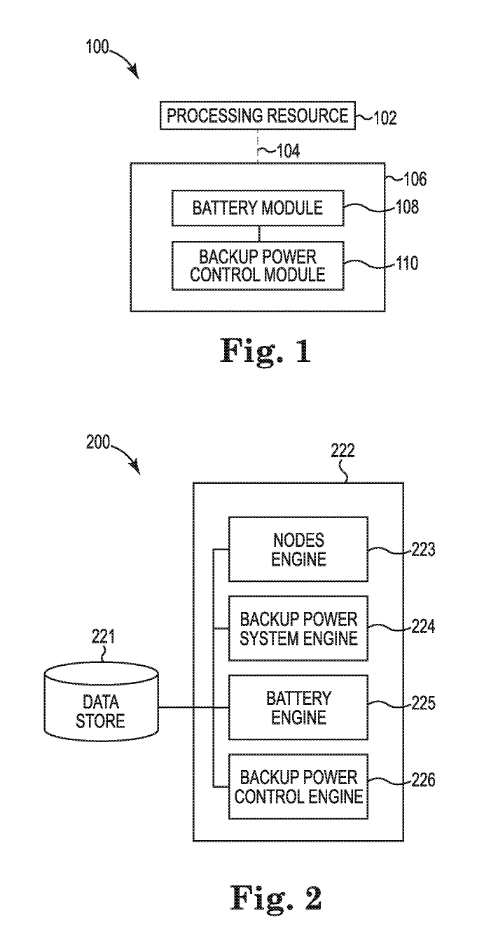

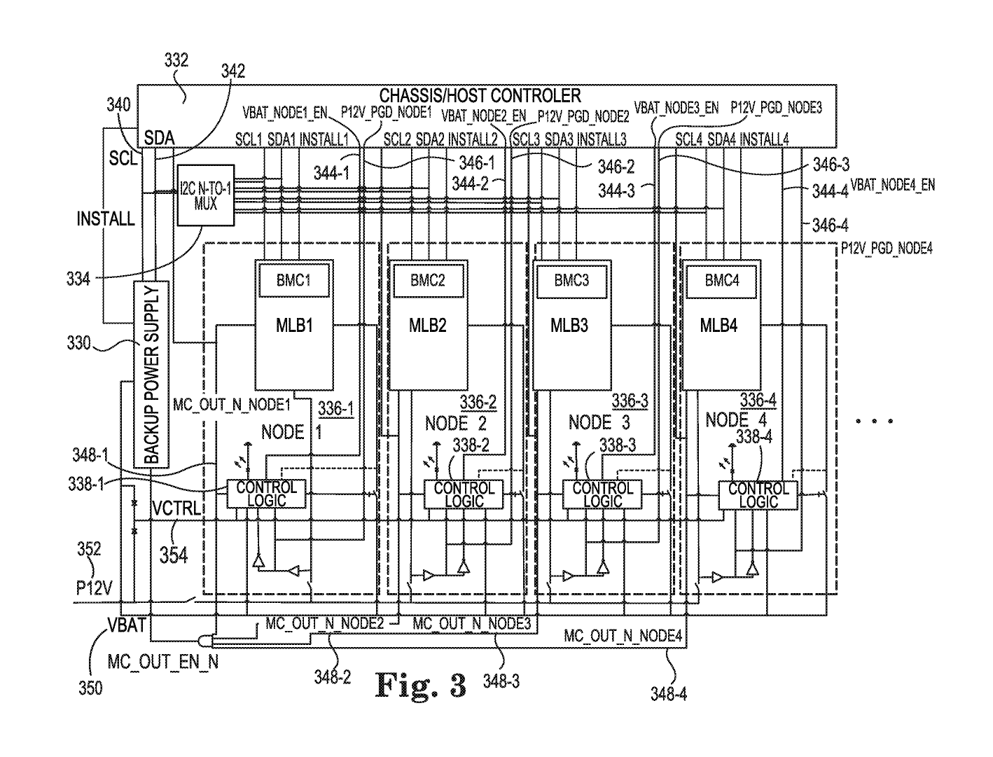

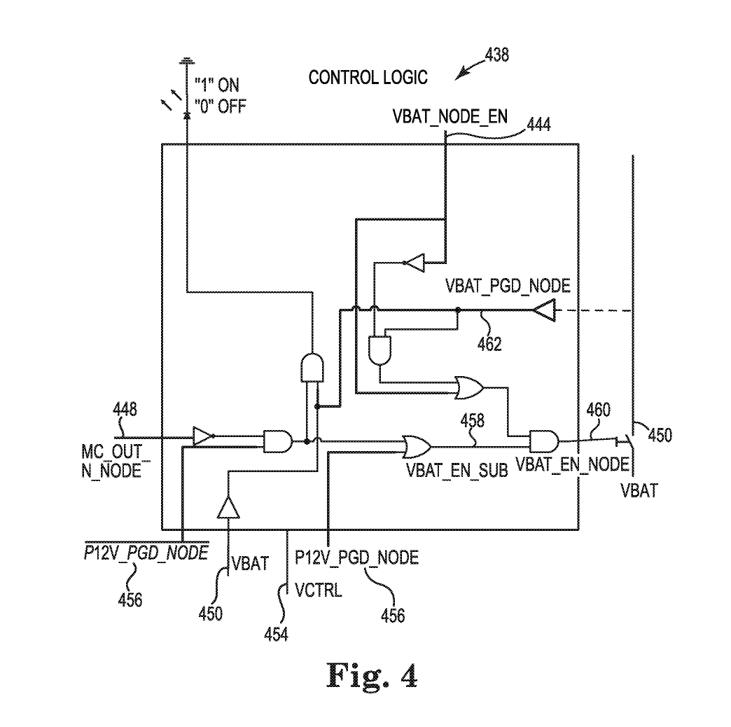

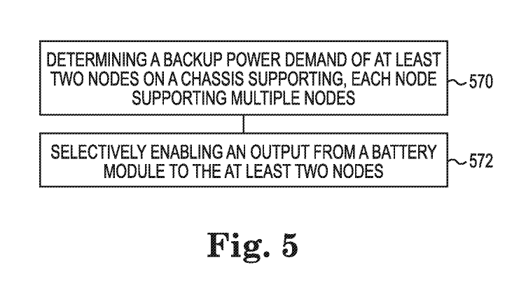

FIG. 1 illustrates a block diagram of an example of a computing device according to the present disclosure. The computing device 100 can include a processing resource 102 connected to a memory resource 106, e.g., a computer-readable medium (ORM), machine readable medium (MRM), database, etc. The memory resource 106 can include a number of computing modules. The example of FIG. 1 shows a battery module 108 and a backup power control 109. As used herein, a computing module can include program code, e.g., computer executable instructions, hardware, firmware, and/or logic, but includes at least instructions executable by the processing resource 102, e.g., in the form of modules, to perform particular actions, tasks, and functions described in more detail herein in reference to FIG. 3, FIG. 4, and FIG. 5. The processing resource 102 executing instructions associated with a particular module, e.g., modules 108 and 109, can function as an engine, such as the example engines shown in FIG. 2.

FIG. 2 illustrates a block diagram of an example of a system 220 for providing force feedback according to the present disclosure. The system 220 can perform a number of functions and operations as described in FIG. 3, FIG. 4, and FIG. 5, e.g., providing backup power. The system 220 can include a data store 221 connected to a power supply system 222. In this example, the power supply system 222 can include a number of computing engines. The example of FIG. 2 shows a nodes engine 223, a backup power system engine 224, a battery engine 225, and a backup power control engine 226. As used herein, a computing engine can include hardware firmware, logic, and/or executable instructions, but includes at least hardware e.g., a processor, executing instructions to perform particular actions, tasks and functions described in more detail herein in reference to FIG. 3, FIG. 4, and FIG. 5.

The number of engines 223, 224, 225, and 226 shown in FIG. 2 and/or the number of modules 108 and 109 shown in FIG. 1 can be sub-engines/modules of other engines/modules and/or combined to perform particular actions, tasks, and functions within a particular system and/or computing device.

Further, the engines and/or modules described in connection with FIGS. 1 and 2 can be located in a single system and/or computing device or reside in separate distinct locations in a distributed computing environment, e.g., cloud computing environment. Embodiments are not limited to these examples.

FIG. 3 illustrates a block diagram of an example of a system for providing backup power according to the present disclosure. FIG. 3 includes a backup power supply 330 a multiplexer (MUX) 334, a chassis/host controller 332, a node 336-1 node 336-1, a node 336-2, a node 336-3, and a node 336-4, e.g., referred to generally as nodes 336. FIG. 3 also includes a number of array control logic units, e.g., array control logic 338-1, array control logic 338-2, array control logic 338-3, and array control logic 338-4, e.g., referred to generally as array control logic 338. FIG. 3 is an example of the backup power system engine 224.

In the embodiment of FIG. 3, array control logic is shown on chassis associated with each node. However, embodiments are no so limited and an array control logic 338 may be separate from the chassis/host and support multiple nodes.

The battery module 108 and/or the battery engine 225 in FIG. 1 and FIG. 2 respectively, can include a backup power supply 330. The backup power supply 330 can be a battery that is external to the number of nodes and external to the chassis/host supporting the number of nodes. The backup power supply 330 can provide power to the nodes 336.

In a number of examples, the backup power supply 330 that can control the power supplied to a number of nodes and identify the state of the nodes 336 that are coupled to the backup power supply 330.

The power supply 330 can be coupled to a signal clock line (SOL) 340 and a signal data line (SDA) 342, and an install line. The SOL 340 and the SDA 342 can connect the backup power supply 330 to the chassis/host controller 332 and to the MUX 334. The MUX 334 can be coupled to the nodes 336. In a number of examples, the backup power supply 330 can be coupled to the chassis/host controller 332 via the install line. The chassis/host controller 332 can be coupled to the nodes 336 via SCL1, SDA1, SCL2, SDA2, SCL3, SDA3, SCL4, and SDA4. The chassis/host controller 332 can also be coupled to the nodes 336 via install1 line 1, install line 2, install line 3, and install line 4. In a number of examples, the install lines can provide for the registering of the nodes with the chassis/host controller 332.

The chassis/host controller 332 can be separate from the chassis supporting the number of nodes and the MUX 334. In a number of examples, the nodes 336 can be connected in parallel on one chassis and can be serially chained to the backup power supply 330 on multiple different chassis.

A node engine 223 in FIG. 2 can include the function of the chassis/host controller 332. Each of the nodes 336 can include a main logic boar (MLB). Each MLB can include a baseboard management control unit (BMC) and/or a number of loads. In a number of examples, the MLB components can allow the nodes 336 to communicate with the backup power supply 330 and the chassis/host controller 332.

The number of loads can be volatile and/or non-volatile memory. For example, the loads can include cache memory, e.g., volatile memory. FIG. 3 shows four (4) nodes, e.g., node 336-1, node 336-2, node 336-2, and node 336-4, as an example. However, fewer or more than four (4) nodes may be provided, e.g., two (2) nodes. Each of the nodes 336 can host a number of loads. For example, each of the nodes 336 can host 2, 4, 6, or 8 loads. In a number of examples, more or fewer loads can be hosted in a node.

If the main power supply is removed, then data can be transferred from the cache memory in the loads to persistent memory, e.g., to a number of non-volatile (NV) dual in-line memory modules (DIMMs) having flash memory, persistent dynamic random access memory (DRAM), etc. For example, data can be moved from cache memory to at least sixteen (16) NV DIMMs having flash memory. In a number of examples, the flash memory of the at least 16 DIMMS can include flash memory having multilevel cells (MLCs). Moving the data can include moving the data to non-volatile memory that is local to the nodes 336, external to the nodes 336, and/or external to the power management system.

In a number of examples, a backup power supply can support nodes on different chassis. That is, a backup power supply can support different chassis/host controllers, e.g., not shown, and different MUXs, e.g., not shown, to support a plurality of nodes on the different chassis.

The SCL 340, the SDA 342 and the MUX 334 can be part of chassis/host controller 332 interface with the backup power supply 330 and the nodes 336. The SCL 340 and the SDA 342 can be used by the chassis/host controller 332 to clock the nodes 336 and/or transfer data from the nodes 336 and to communicate this information to the backup power supply 330. For example, the chassis/host controller 332 can clock the nodes 336 in communication with the backup power supply 330 via the SOL 340. The chassis/host controller 332 can control management of the nodes 336 under both primary and backup power supply. The chassis/host controller's 332 control management function for the nodes 336 can include the addition and/or removal of the node connections. Adding and/or removing the nodes 336 can include dynamically coupling the nodes 336 to a chassis.

In the example management interface between the chassis/host controller 332 and the backup power supply 330 shown in FIG. 3, the MUX 334 is shown to include an n-to-1 multi-master 120 MUX. N can represent the quantity of nodes that can be coupled to the backup power supply 330. For example, FIG. 3 includes four nodes and as a result the MUX 334 can be a 4-to-1 MUX. Embodiments, however, are not limited to this example embodiment.

As stated, the chassis/host controller 332 includes circuitry that can be used to control, add, remove, and/or register nodes with the chassis. The chassis/host controller 332 can also control operation of the nodes 336 such as the movement of data from volatile memory (e.g., cache) to persistent memory, e.g., to non-volatile memory (persistent DRAM, flash, etc).

In a number of examples, the chassis/host controller 332 can be coupled to array control logic 338. Backup power control module 109 and backup power control engine 226 in FIG. 1 and FIG. 2 can include the array control logic 338. The array control logic 338 can be used to determine whether backup power from the backup power supply 330 should be supplied to nodes 336. FIG. 4 describes an example of determining whether backup power should be supplied to a node.

The chassis/host controller 332 can be coupled to the number of nodes via a number of signal control lines. For example, the chassis/host controller 332 can be coupled to the array control logic 338 via the backup energy node enabled line (Vbat_Node1_EN) 334-1 to signal the backup power supply is enabled for NODE 1. The signal lines (P12V_PGD_Node1) 346-1 can communicate the primary power supply status between the chassis/host controller 332 and the array control logic 338 for each of the respective nodes 336. The (MC_OUT_N_NODE1) 348-1 signal line between the chassis/host controller 332 and the array control logic 338 for NODE 1 can signal a “dirty” (e.g., data present and not previously backed up) or “clean” (e.g., data not present or previously backed up) non-volatile (e.g., cache) memory status. In a similar manner, the chassis/host controller 332 can be coupled to array control logic 338-2 via the Vbat_Node2_EN 334-2, the P12V_PGD_Node2 346-2, and the MC_OUT_N_NODE2 348-2. The chassis/host controller 332 can be coupled to array control logic 338-3 via the Vbat_Node3_EN 334-3, the P12V_PGD_Node3 346-3, and the MC_OUT_N_NODE3 348-3. The chassis/host controller 332 can be coupled to array control logic 338-4 via the Vbat_Node4_EN 334-4, the P12V_PGD_Node4 346-4, and the MC_OUT_N_NODE4 348-4.

The Vbat_Node1_EN 334-1, Vbat_Node2_EN 334-2, Vbat_Node3_EN 334-3, and Vbat_Node4_EN 334-4 are generally referred to as Vbat_Node_EN 334. The Vbat_Node_EN 334 is a signal that is used to control an e-fuze to provide backup power from the backup power source 330. An e-fuse is an electronically controlled fuze, e.g., transistor controlled fuse.

The P12V_PGD_Node1 346-1, P12V_PGD_Node2 346-2, P12V_PGD_Node3 346-3, and P12V_PGD_Node4 346-4 are referred to generally as P12V_PGD_Node 346. The P12V_PGD_Node3 346-3 is a signal that identifies whether the main power source is active.

The MC_OUT_N_NODE1 348-1, the MC_OUT_N_NODE2 348-2, the MC_OUT_N_NODE3 348-3, and the MC_OUT_N_NODE4 348-4 are referred to generally as the MC_OUT_N_NODE 348. The MC_OUT_N_NODE 348 is a signal that identifies whether the nodes 336 have dirty cache. Dirty cache can reference cache that contains data that has not been moved to non-volatile memory. That is, dirty cache identifies if there is data that needs to be backed-up.

In a number of examples, the array control logic 338 can be coupled to the nodes via MC_OUT_N_NODE 348. For example, the nodes 336 can provide a voltage to the MC_OUT_N_NODE 348 when data needs to be backed up to non-volatile memory. The MC_OUT_N_NODE 348 can also couple the chassis/host controller 332 to the nodes 336 and the array control logic 338.

In a number of examples, the backup power supply 330 can provide a power to the array control logic 338 and the nodes 336 via a backup power control line (Vctrl) 354. The Vctrl 354 can be coupled to both the main power line (P12V) and the backup power line (Vbat) 350. That is, the Vctrl 353 can provide power to the array control logic 338 via a main power supply and/or a backup power supply 330. In a number of examples, the backup power supply 330 can provide power to the array control logic 338 which in turn can be used to activate the Vbat 350 to supply power to the nodes 336.

In a number of examples, the P12V can provide a same voltage and/or a different voltage, e.g., power, to the array control logic 338 and the nodes 336, than a voltage provided by the backup power supply 330 via Vbat 350 and/or Vctrl 354. For example, the main power source can provide 12 volts via the P12V while the backup power supply can provide a different voltage via the Vbat 350 and/or Vctrl 354.

FIG. 4 illustrates a diagram of an example of array control logic 438 according to the present disclosure. Array control logic 438 is analogous to array control logic 338 in FIG. 3. The array control logic 438 can receive a number of inputs. For example, array control logic 438 can receive as input a Vbat_Node_EN 444, MC_OUT_N_NODE 448, and P12V_PGD_NODE 446 that are analogous to Vbat_Node_EN 344, MC_OUT_N_NODE 348, and P12V_PGD_NODE 346 in FIG. 3, respectively, and backup power node line (Vbat_PGD_NODE) 462. Vbat_PGD_NODE 462 can indicate whether the backup power supply is active.

FIG. 4 is an example of backup power control module 110 and/or backup power control engine 226 in FIG. 1 and FIG. 2, respectively. Array control logic 438 can receive a number of inputs from the chassis, the nodes, the backup power supply, and/or the main power supply to determine whether to provide power from the backup power supply to a node for data backup services. In a number of examples, the array control logic 438 can use Boolean logic, e.g., AND, OR, NOT, among other possible Boolean logical operations, to determine whether to provide power to the nodes from the backup power supply.

In FIG. 4, the array control logic 438 uses a two part function to determine whether to activate Vbat 450 to provide data to a node. A first part of the array control logic 438 can produce an intermediary result, e.g., backup power enabled subsystem line (VBAT_EN_SUB) 458, which can be used as input to the second part of the array control logic 438. The result of the two part function is given via a backup enabled node line (Vbat_EN_NODE) 460.

The following truth table, e.g., Table 1, is an example of a first part of a function that in part defines the array control logic 438:

TABLE 1
First Truth Table for Array Control Logic 438

| MC_OUT_N_NODE | P12V_PGD_NODE | VBAT_EN_SUB |
|---|---|---|
| 1 | 1 | 1 |
| 1 | 0 | 0 |
| 0 | 1 | 1 |
| 0 | 0 | 1 |

The first part of a function that in part defines the array control logic 438 receives as input MC_OUT_N_NODE 448 and P12V_PGD_NODE 446. The result of the first part of the function is given in VBAT_EN_SUB 458. For example, MC_OUT_N_NODE can hold a high voltage, e.g., 1, if there is no data that needs to be backed-up or a low voltage, e.g., 0, if there is data that needs to be backed-up, e.g., dirty cache. The P12V_PGD_NODE can hold a high voltage, e.g., 1, if the main power supply is active and a low voltage, e.g., 0, if the main power supply is not active.

In the first truth table, e.g., Table 1, the VBAT_EN_SUB 458 provides a low voltage if there is no dirty cache, e.g., MC_OUT_N_NODE 448 provides a high voltage (1), and the main power supply is active, e.g., P12V_PGD_NODE provides a high voltage (1). VBAT_EN_SUB 458 can provide a low voltage (0) if there is no dirty cache, e.g., MC_OUT_N_NODE 448 provides a high voltage (1), and the main power supply is inactive, e.g., P12V_PGD_NODE provides a low voltage (0). VBAT_EN_SUB 458 can provide a high voltage (1) if there is dirty cache, e.g., MC_OUT_N_NODE 448 provides a low voltage (0), and the main power supply is active, e.g., P12V_PGD_NODE provides a high voltage (1). VBAT_EN_SUB 458 can provide a high voltage (1) if there is dirty cache, e.g., MC_OUT_N_NODE 448 provides a low voltage (0), and the main power supply is inactive, e.g., P12V_PGD_NODE provides a low voltage (0).

The following truth table, e.g., Table 2, is an example of a second part of a function that in part defines the array control logic 438:

TABLE 2
Second Truth Table for Array Control Logic 438

| Vbat_EN_SUB | Vbat_NODE_EN | Vbat_PGD_NODE | Vbat_EN_NODE |
|---|---|---|---|
| 1 | 1 | 1 | 1 |
| 1 | 1 | 0 | 1 |
| 1 | 0 | 1 | 1 |
| 1 | 0 | 0 | 0 |
| 0 | 1 | 1 | 0 |
| 0 | 1 | 0 | 0 |
| 0 | 0 | 1 | 0 |
| 0 | 0 | 0 | 0 |

In the second truth table, e.g., Table 1, Vbat_EN_NODE 460 provides a high voltage (1) if Vbat_EN_SUB 458 provides a high voltage (1), Vbat_NODE_EN 438 provides a high voltage (1), and Vbat_PGD_NODE 462 provides a high voltage (1). Vbat_EN_NODE 460 provides a high voltage (1) if Vbat_EN_SUB 458 provides a high voltage (1). Vbat_NODE_EN 438 provides a high voltage (1), and Vbat_PGD_NODE 462 provides a low voltage (1). Vbat_EN_NODE 460 provides a high voltage (1) if Vbat_EN_SUB 458 provides a high voltage (1), Vbat_NODE_EN 438 provides a low voltage (0), and Vbat_PGD_NODE 462 provides a high voltage (1). Vbat_EN_NODE 460 provides a low voltage (0) if Vbat_EN_SUB 458 provides a high voltage (1), Vbat_NODE_EN 438 provides a low voltage (0), and Vbat_PGD_NODE 462 provides a low voltage (0). Vbat_EN_NODE 460 provides a low voltage (0) if Vbat_EN_SUB 458 provides a low voltage (0), Vbat_NODE_EN 438 provides a high voltage (1), and Vbat_PGD_NODE 462 provides a high voltage (1). Vbat_EN_NODE 460 provides a low voltage (0) if Vbat_EN_SUB 458 provides a low voltage (0), Vbat_NODE_EN 438 provides a high voltage (1), and Vbat_PGD_NODE 462 provides a low voltage (0). Vbat_EN_NODE 460 provides a low voltage (0) if Vbat_EN_SUB 458 provides a low voltage (0), Vbat_NODE_EN 438 provides a low voltage (0), and Vbat_PGD_NODE 462 provides a high voltage (1). Vbat_EN_NODE 460 provides a low voltage (0) if Vbat_EN_SUB 458 provides a low voltage (0), Vbat_NODE_EN 438 provides a low voltage (0), and Vbat_PGD_NODE 462 provides a low voltage (0). Vbat_EN_NODE 460 can provide a high voltage to provide backup power to a node. Vbat_EN_Node 460 can provide a low voltage to restrict backup power to the node.

FIG. 5 illustrates a flow diagram of an example of a method for providing backup power according to the present disclosure. At 570, a backup power demand can be determined. The backup power supply supports at least two nodes on a chassis. Each node supports multiple loads. In a number of examples a power backup demand can vary based on the number of loads that the backup power supply supports. For example, more power can be drawn from the backup power supply if the backup powers supply supports four loads rather than two loads. In a number of examples, the backup power demand can be determined in backup power supply and/or a chassis that is separate from the backup power supply.

At 572, an output from a battery module to the at least two nodes can be selectively enabled. Selectively enabling the output can include providing power from the backup power supply to a portion of the number of nodes that are coupled to the backup power supply. For, example, a determination can be made to provide power from the backup power supply to a first node and to not provide power from the backup power supply to a second node, both the first node and the second node being coupled to the backup power supply. A determination to provide power to the first node can be, for example, made because the first node has cache that needs to be backed-up. Furthermore, a determination not to provide power to the second node can be made because the second node has cache that does not need to be backed-up. In a number of examples, selectively enabling the output can be performed in a number of array control logic units that control whether the nodes receive power from the backup power supply.

In a number of embodiments, a backup power supply can support more than a fixed number of loads in parallel by sequentially enabling the backup power supply to provide power to the nodes 336. For example, if a particular fixed number of loads that a backup power supply can support is 24 loads, then by sequentially enabling a connection of the backup power supply to the nodes the backup power supply may support a number of loads greater than 24, e.g., 36 loads, 48 loads, etc., on the nodes 336 via sequencing. The sequencing can be performed via a chassis/host controller 332 in communication with the backup power supply 330. That is, the chassis/host controller can control sequencing a backup power to according received input for a plurality of loads greater than 24 loads. In one example, a backup power supply can support more than 24 loads by sequencing backup power to first group of loads, e.g., 24 loads, and not a second group of loads, e.g., another 24 loads on a same or different chassis. In this example, after a predetermined amount of time, the backup power supply can provide backup power to the second group of loads and not the first group of loads.

In this example, providing power by sequencing can include alternating the enabling of connections between the backup power supply 330 and the nodes 336. For example, during a first time interval the first group of loads can receive backup power supply connection but not the second group of loads. During a second time interval the second group of loads can receive backup power supply connection but not the first group of loads. During a third time interval the first group of loads can again receive backup power but not the second group of loads. In a number of examples, providing power by sequencing can include providing power by alternating power between individual nodes.

In a number of examples, a separate array control logic unit can determine whether to provide power from the backup power supply to each of the nodes. A first array control logic unit can determine to provide power to a first node while a second array control logic unit can determine to provide power to a second node, the first node being separate from the second node.

In a number of examples, nodes can be added, e.g., coupled to, or removed, e.g., decoupled, from the backup power supply. Adding or removing nodes from the backup power supply can include signaling a chassis/host controller for the at least two nodes upon an addition or a removal of a node from the chassis. In a number of examples, signaling a chassis/host controller can include signaling a MUX that functions as a chassis/host controller. The chassis/host controller can signal the node by clocking the node. Adding or removing the backup power supply can enable the backup power supply to provide power to a first quantity of nodes at a first time and a second quantity of nodes at a second time.

Determining the backup power demand of the at least two nodes supporting the multiple loads can include determining a backup power demand to transfer data from volatile, e.g., cache, memory in the multiple loads to each of multiple array controllers and to persistent memory, e.g., to non-volatile memory. Non-volatile memory may include by way of example, and not by way of limitation, multiple non-volatile dual in-line memory modules (NV-DIMMs) having multilevel cell (MLC) flash memory. Embodiments, however, are not so limited. The transfer of data can occur, for example, when a main power supply becomes inactive, for example, based on a failure of the main power supply. A signal can be provided to the array control logic indicating removal of a primary power supply. Removal of the main power supply can trigger a determination, by the array control logic, to provide power from the backup power supply to the number of nodes.

In a number of examples, a determination to provide power form the backup power supply to the number of nodes can include providing the output of power from the battery module to each of the selected nodes in parallel. Providing the output of power form the battery module to each of the selected nodes in parallel can enable the nodes to perform backup functions in parallel.

In a number of examples, a backup power supply can provide power to a plurality of nodes and a plurality of chassis array controllers that are coupled to different chassis. For example, a backup power supply can provide power to a first number of nodes and a first number of array controllers via a first chassis and a second number of nodes and a second number of array controllers via a second chassis.

In a number of examples, the backup power supply can provide the output of power to each of six (6) array controllers and to each of sixteen (16) NV-DIMMs on one chassis in parallel and to another number of nodes supporting multiple loads on a different chassis sequentially for more than a specified time period. For example, backup power can be provided for more than a 90 second time period, more than a 60 second time period, and/or more than a 30 second time period. In a number of examples, the backup power supply can provide up to 160 second of power.

In the present disclosure, reference is made to the accompanying drawings that form a part hereof, and in which is shown by way of illustration how a number of examples of the disclosure can be practiced. These examples are described in sufficient detail to enable those of ordinary skill in the art to practice the examples of this disclosure, and it is to be understood that other examples can be used and that process, electrical, and/or structural changes can be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. As used herein, the designators “N” and “M”, among others, indicate that a number of the particular feature so designated can be included with a number of examples of the present disclosure. In addition, the proportion and the relative scale of the elements provided in the figures are intended to illustrate the examples of the present disclosure, and should not be taken in a limiting sense.

The specification examples provide a description of the applications and use of the system and method of the present disclosure. Since many examples can be made without departing from the spirit and scope of the system and method of the present disclosure, this specification sets forth some of the many possible example configurations and implementations.

As used herein, “a” or “a number of” something can refer to one or more such things. For example, “a number of widgets” can refer to one or more widgets.

What is claimed:

1. A data storage system, comprising:
at least two (2) nodes supporting at least twenty four (24) loads; and
a backup power system operatively coupled to the at least two nodes to support the twenty four loads in an event of a removal of a primary power supply, the backup power system including:
a battery module; and
a backup power control module having instructions stored in a non-transitory medium and executed by a processing resource to determine a backup power demand of at least one load to the at least twenty four loads and selectively provide backup power from the battery module to the twenty four loads in parallel.

2. The system of claim 1, wherein the backup power control module includes instructions executed by the processing resource to selectively provide backup power to at least six (6) array controllers.

3. The system of claim 2, wherein the at least twenty four loads include the at least six array controllers and a data transfer from cache memory to at least sixteen (16) non-volatile (NV) dual in-line memory modules (DIMMs) having flash memory.

4. The system of claim 3, wherein the flash memory of the at least 16 DIMMs includes flash memory having multilevel cells (MLCs).

5. The system of claim 1, wherein the backup power supply is serially chained to at least another four nodes, supporting additional loads, on a separate chassis.

6. The system of claim 1, wherein the at least two (2) nodes are on a single chassis, the backup power system is separate from the chassis, and the backup power system selectively provides power to the at least two (2) nodes on the chassis through a single chassis control logic circuit.

7. The system of claim 6, where in the single chassis control logic circuit is separate from the chassis.

8. A data storage apparatus, comprising:
a battery module; and
a backup power control module having instructions stored in a non-transitory medium and executed by a processing resource to control providing backup power from the battery module to at least six (6) on chassis control circuits and at least sixteen (16) on chassis non-volatile dual inline memory modules (NV-DIMMs).

9. The apparatus of claim 8, wherein the 16 NV-DIMMs include persistent memory.

10. The apparatus of claim 8, the backup power control module including instructions that are executed to control providing backup power from the battery module to at least four (4) servers supporting at least twenty four (24) loads in parallel and to another four (4) servers supporting an additional twenty four (24) loads, sequentially, for a period of at least 90 seconds.

11. A method of providing backup power to a number of nodes, comprising:
determining a backup power demand of at least two nodes on a chassis, each node supporting multiple loads; and
selectively enabling an output of power from a battery module to the at least two nodes.

12. The method of claim 11, wherein the method includes signaling a chassis controller for the at least two nodes upon an addition or a removal of a node from the chassis.

13. The method of claim 11, wherein determining the backup power demand of the at least two nodes supporting the multiple loads includes determining a backup power demand to transfer data from cache memory to each of multiple array controllers and multiple non-volatile dual in-line memory modules (NV-DIMMs) having multilevel cell (MLC) flash memory.

14. The method of claim 13, wherein the method includes:
receiving a signal indicating a removal of a primary power supply;
providing the output of power from the battery module to each of the selected nodes in parallel.

15. The method of claim 13, wherein the method includes providing the output of power from the battery module to each of six (6) array controllers and to each of sixteen (16) NV-DIMMs on one chassis in parallel and to another number of nodes supporting multiple loads on a different chassis sequentially for a time period of more than 60 seconds.
